(19) United States
(12) Patent Application Publication
(10) Pub. No.: US 2002/0109555 A1
(43) Pub. Date: Aug. 15, 2002

(54) Voltage-controlled variable tuning circuit for switching an oscillation frequency band of a voltage controlled oscillator

(76) Inventor: Soo-Seul Hwang, Kumi-shi (KR)

Correspondence Address: Paul J. Farrell, DILWORTH & BARRESE, LLP, 333 Earle Ovington Blvd, Uniondale, NY, 11553, US

(21) Appl. No.: 09/999,427

(22) Filed: Oct. 31, 2001

(30) Foreign Application Priority Data
Feb. 12, 2001 (KR) 2001-6665

(51) Int. Cl. H03B 7/12

(52) U.S. Cl. 331/100

(57) ABSTRACT

Disclosed is a voltage-controlled variable tuning circuit for switching an oscillation frequency band of a VCO (Voltage Controlled Oscillator), which is available even for a higher frequency band. The voltage-controlled variable tuning circuit comprises a control voltage supply terminal for receiving a control voltage for switching an oscillation frequency; a first capacitor interposed between the control voltage supply terminal and an oscillation circuit; a variable capacitor interposed between the control voltage supply terminal and a reference voltage terminal; an inductor connected in parallel to the variable capacitor; and a frequency band switching circuit with a second capacitor, for selectively connecting the second capacitor in parallel to the first capacitor according to a frequency band.

### PRIORITY

This application claims priority to an application entitled “Voltage-Controlled Variable Tuning Circuit for Switching Oscillation Frequency Band of a Voltage Controlled Oscillator” filed in the Korean Industrial Property Office on Feb. 12, 2001 and assigned Ser. No. 2001-6665, the contents of which are hereby incorporated by reference.

### BACKGROUND OF THE INVENTION

1. Field of the Invention

The present invention relates generally to a VCO (Voltage Controlled Oscillator), and in particular, to a voltage-controlled variable tuning circuit for switching an oscillation frequency band of the VCO.

2. Description of the Related Art

In general, a VCO has a voltage-controlled variable tuning circuit for varying an oscillation frequency depending on a control voltage provided from the outside. FIG. 1 illustrates a circuit diagram of a conventional VCO in which an oscillation circuit 12 is connected to a voltage-controlled variable tuning circuit 10 using a varactor diode 18, which is typically a variable capacitor. Referring to FIG. 1, the voltage-controlled variable tuning circuit 10 is interposed between a control voltage supply terminal 14 and the oscillation circuit 12, and the oscillation circuit 12 is interconnected between the voltage-controlled variable tuning circuit 10 and an output terminal 16. The voltage-controlled variable tuning circuit 10 comprises a capacitor 20 intervening between the control voltage supply terminal 14 and the oscillation circuit 12, the varactor diode 18 connected between the control voltage supply terminal 14 and a reference voltage terminal (ground terminal), and an inductor 22 connected in parallel to the varactor diode 18. A DC (Direct Current) control voltage Vt is provided to the control voltage supply terminal 14. When the conventional VCO shown in FIG. 1 is used in a PLL (Phase Locked Loop), the control voltage Vt is provided from a loop filter. However, when the conventional VCO is used in a mobile communication terminal, the inductor 22 is generally embodied using a microstrip line instead of a chip inductor to stabilize the resonance characteristics of the VCO by improving a Q value determining the resonance characteristics.

In the above-mentioned VCO, a resonance frequency of the voltage-controlled variable tuning circuit 10 is determined according to a capacitance of the varactor diode 18, a capacitance of the capacitor 20 and an inductance of the inductor 22. Here, the varactor diode 18 serves as a variable capacitor whose capacitance varies according to an input bias voltage. Therefore, the resonance frequency of the voltage-controlled variable tuning circuit 10 varies according to the control voltage Vt. As a result, the oscillation frequency of the VCO depends upon the control voltage Vt.

In some cases, a receiver shares a local oscillator with a transmitter in the mobile communication terminal.

A DECT (Digital European Cordless Telephone) system, a European digital mobile telephone, uses a frequency band of 1880 to 1900 MHz, and adopts a TDD (Time Division Duplex) technique which separates transmission signals and reception signals using an RF (Radio Frequency) switch. In order to embody such a DECT system, a VCO operating in the frequency band of 1880 to 1900 MHz and another VCO operating in the frequency band of 1770 to 1790 MHz is used at the transmitter and the receiver, respectively. This is because the VCO, although it can vary an oscillation frequency depending on the control voltage, deviates from a variable scope of the oscillation frequency when the frequency bands are different as stated above, it is not possible to prevent the deviation with a single VCO. However, when the DECT system is embodied using two VCOs as stated above, an additional loop filter and a PLL IC (Integrated Circuit) for the transmitter and the receiver are required to construct a PLL circuit, increasing the complexity of the system.

In order to solve this problem, a VCO that can switch the two different frequency bands of 1880 to 1900 MHz for the transmitter and 1770 to 1790 MHz for the receiver in sync with an antenna switch, can be used to simplify the system. An example of this technique is disclosed in Japanese Patent Laid-Open No. 09-148888, entitled “Voltage-Controlled Variable Tuning Circuit”. The corresponding U.S. Pat. No. 5,808,531, issued on Sep. 15, 1998, discloses a voltage-controlled variable tuning circuit, in which the inductor 22 of the voltage-controlled variable tuning circuit of FIG. 1 is made with two microstrip lines connected in series and one or both of the two microstrip lines is (are) optionally connected by a frequency band switching circuit according to the frequency band. That is, the disclosed voltage-controlled variable tuning circuit switches an oscillation frequency band by changing an inductance of the inductor by varying the length of the microstrip line according to the frequency band, thereby making it possible to cover two different frequency bands using a single VCO.

However, the voltage-controlled variable tuning circuit disclosed in the Japanese Patent Laid-Open No. 09-148888 has the following disadvantages. First, the length of the microstrip line should be shortened when a higher frequency band is used in the system. In this case, it is difficult to embody such a short microstrip line. Second, in general, a 50-Ω line must be used in order to connect the two microstrip lines and interpose the frequency band switching circuit between the microstrip lines. In this case, it is difficult to interpose the 50-Ω line between the two short microstrip lines, and it is also difficult to embody a microstrip line with an accurate inductance for a required resonance frequency because the 50-Ω line operates as an inductor in an RF circuit. Third, when the width of the 50-Ω line intervening between the two microstrip lines is different from that of the microstrip line, a mismatch between the 50-Ω line and the microstrip line results, which undesirably influences a Q value determining resonance performance.

### SUMMARY OF THE INVENTION

It is, therefore, an object of the present invention to provide an improved voltage-controlled variable tuning circuit for switching a frequency band in a VCO, which is available even for a higher frequency band.

To achieve the above object, there is provided a voltage-controlled variable tuning circuit for switching an oscillation frequency band of a VCO. The voltage-controlled variable tuning circuit comprises a control voltage supply terminal for receiving a control voltage for switching an oscillation frequency, a first capacitor interposed between the control voltage supply terminal and an oscillation circuit, a variable capacitor interposed between the control voltage supply terminal and a reference voltage terminal, an inductor connected in parallel to the variable capacitor, and a frequency band switching circuit with a second capacitor, for selectively connecting the second capacitor in parallel to the first capacitor according to a frequency band.

### BRIEF DESCRIPTION OF THE DRAWINGS

The above and other objects, features and advantages of the present invention will become more apparent from the following detailed description when taken in conjunction with the accompanying drawings in which:

FIG. 1 is a circuit diagram of a conventional VCO;

FIG. 2 is a circuit diagram of a VCO according to an embodiment of the present invention;

FIG. 3 is a diagram illustrating a harmonic characteristic simulation result for a transmission frequency band of the VCO illustrated in FIG. 2;

FIG. 4 is a diagram illustrating a harmonic characteristic simulation result for a reception frequency band of the VCO illustrated in FIG. 2;

FIGS. 5A and 5B are diagrams illustrating measured variable scopes of the transmission frequency band of the VCO illustrated in FIG. 2; and

FIGS. 6A and 6B are diagrams illustrating measured variable scopes of the reception frequency band of the VCO illustrated in FIG. 2.

### DETAILED DESCRIPTION OF THE PREFERRED EMBODIMENT

A preferred embodiment of the present invention will be described herein below with reference to the accompanying drawings. In the following description, well-known functions or constructions are not described in detail since they would obscure the invention in unnecessary detail.

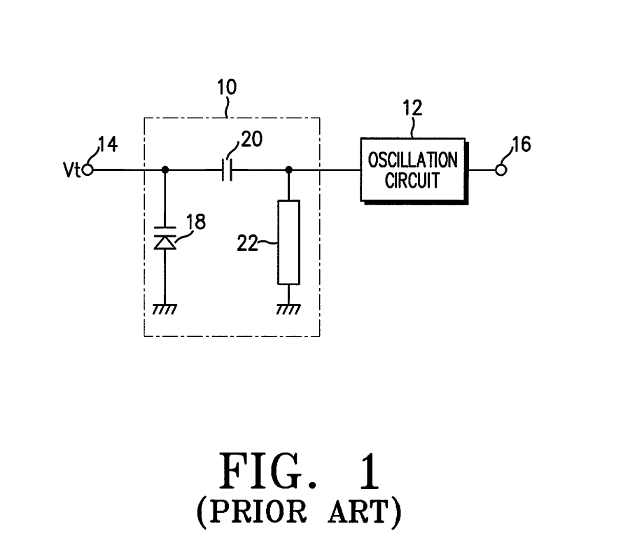

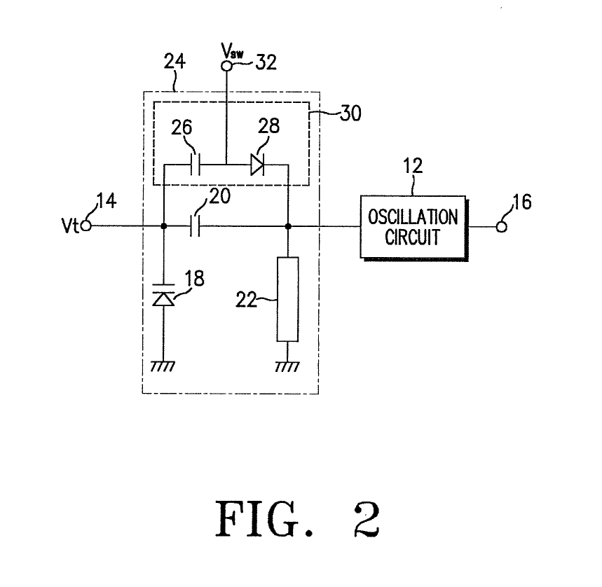

FIG. 2 shows a circuit diagram of a VCO having a voltage-controlled variable tuning circuit 24 according to an embodiment of the present invention. Referring to FIG. 2, the voltage-controlled variable tuning circuit 24 includes a frequency band switching circuit 30 in addition to the voltage-controlled variable tuning circuit 10 shown in FIG. 1. The frequency band switching circuit 30 comprises a capacitor 26 and a diode 28, and selectively connects the capacitor 26 in parallel to the capacitor 20 according to a frequency band.

More specifically, the frequency band switching circuit 30 comprises the capacitor 26, the diode 28 and a frequency band switching control voltage supply terminal 32. The capacitor 26 and the diode 28 are serially connected with each other and connected in parallel to the capacitor 20. The frequency band switching control voltage supply terminal 32 is connected to a connection point between the capacitor 26 and the diode 28, and is used to supply a frequency band switching control voltage V_{SW} to the connection point. Here, the diode 28 is used as a switching element that is turned on or off according to a level of the frequency band switching control voltage V_{SW}. For this purpose, an anode of the diode 28 is connected to the capacitor 26 and the frequency band switching control voltage supply terminal 32, and a cathode of the diode 28 is connected to a connection point between the capacitor 20 and the inductor 22. In the case of the DECT system, the frequency band switching control voltage V_{SW} corresponds to the signal used to switch the antenna switch for selecting a transmission or reception mode. For example, the level of the frequency band switching control voltage V_{SW} becomes “LOW” in the transmission mode, and “HIGH” in the reception mode.

More specifically, if the level of the frequency band switching control voltage V_{SW} is “HIGH”, the diode 28 is turned on, so that the capacitor 26 is connected in parallel to the capacitor 20. In this case, the resonance frequency of the voltage-controlled variable tuning circuit 24 is determined according to the inductance of the inductor 22 and the combined capacitance of the varactor diode 18 and the capacitors 20 and 26. Otherwise, if the level of the frequency band switching control voltage V_{SW} is “LOW”, the diode 28 is turned off, so that the capacitor 26 is open circuited. In this case, the resonance frequency is determined according to the inductance of the inductor 22 and the combined capacitance of the varactor diode 18 and the capacitors 20.

Consequently, by turning the diode 28 on or off according to the frequency band switching control voltage V_{SW} and thus varying the total capacitance and the resonance frequency of the voltage-controlled variable tuning circuit 24, the voltage-controlled variable tuning circuit 24 can cover two different frequency bands using a single VCO.

Moreover, since the resonance frequency of the voltage-controlled variable tuning circuit 24 is switched by varying the capacitance instead of the inductance (i.e., the length of the inductor 22), it is easy to embody the voltage-controlled variable tuning circuit 24 even for the higher frequency band.

For reference, a description will be made regarding a simulation result and an actual measurement result of the circuit shown in FIG. 2 when it is used in common for transmission and reception in the DECT system. A microwave design system (MDS), a high-frequency circuit design simulator, made by Hewlett-Packard is used for the simulation. An ISV229 varactor diode made by Toshiba, an HVC132 PIN diode made by Hitachi and an 8564E spectrum analyzer made by Hewlett-Packard are used for the actual measurement.

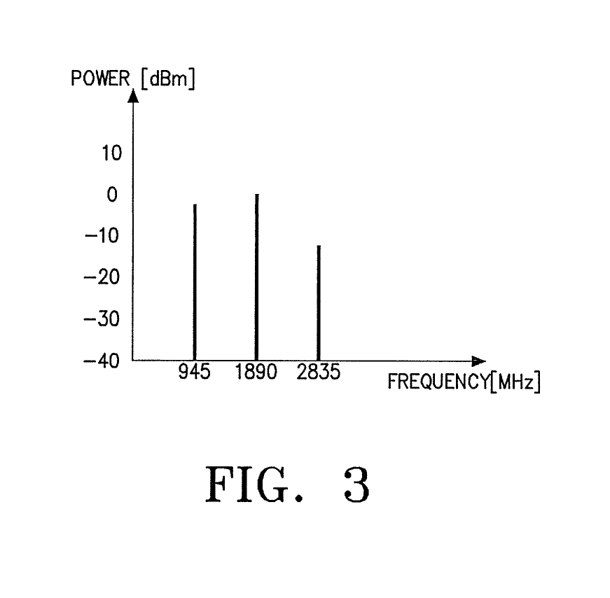

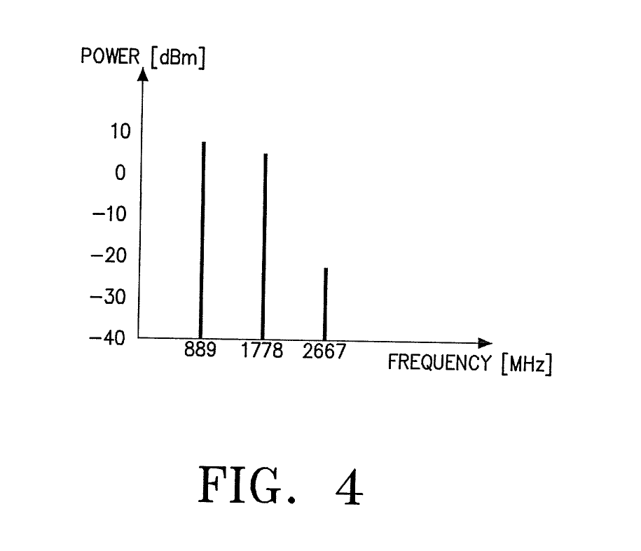

FIG. 3 illustrates a harmonic characteristic of a transmission frequency band of the VCO illustrated in FIG. 2, which is simulated by the MDS when the fundamental frequency of the transmission frequency band is 945 MHz, and FIG. 4 illustrates a harmonic characteristic of a reception frequency band of the VCO illustrated in FIG. 2, which is simulated by the MDS when the fundamental frequency of the reception frequency band is 889 MHz. FIG. 3 illustrates the output power levels of the fundamental frequency and harmonic components at an RF output terminal in the transmission frequency band, and FIG. 4 illustrates the output power levels of the fundamental frequency and harmonic components at an RF terminal in the reception frequency band. Referring to FIGS. 3 and 4, the level of the second harmonic component is set to be similar to that of the fundamental frequency. In this case, when the harmonic component of the active element is applied to the PLL circuit embodied using the circuit illustrated in FIG. 2, once the PLL circuit is locked to a 900 MHz band, it is also locked to 1800 MHz band, which is a second harmonic frequency band. Therefore, the VCO covers not only 900 MHz transmission/reception bands but also 1800 MHz transmission/reception bands. In short, a PLL circuit constructed with the VCO shown in FIG. 2 can cover four different frequency bands (the 900 MHz transmission/reception bands and the 1800 MHz transmission/reception bands) using a single VCO.

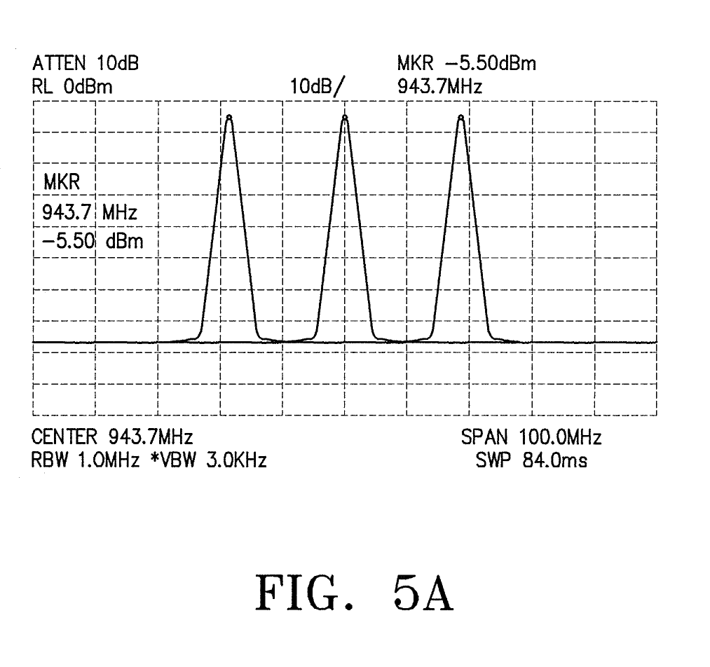

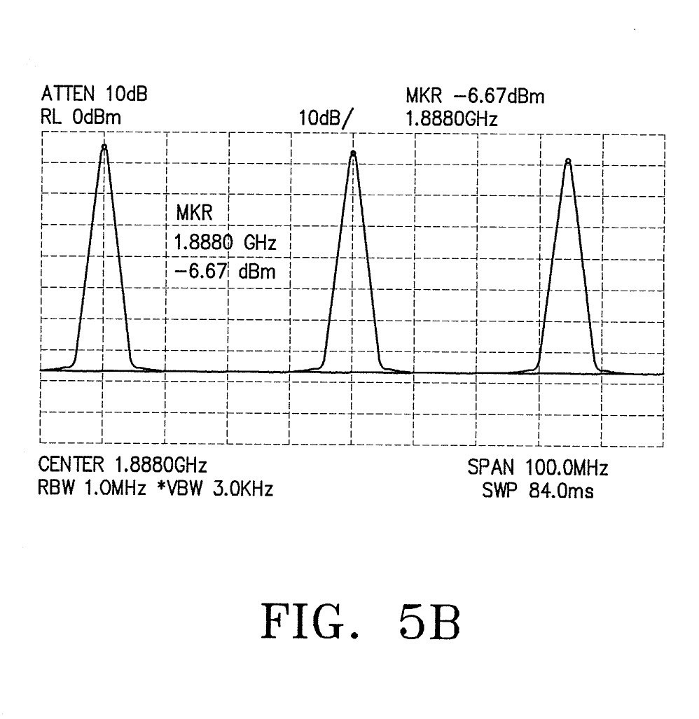

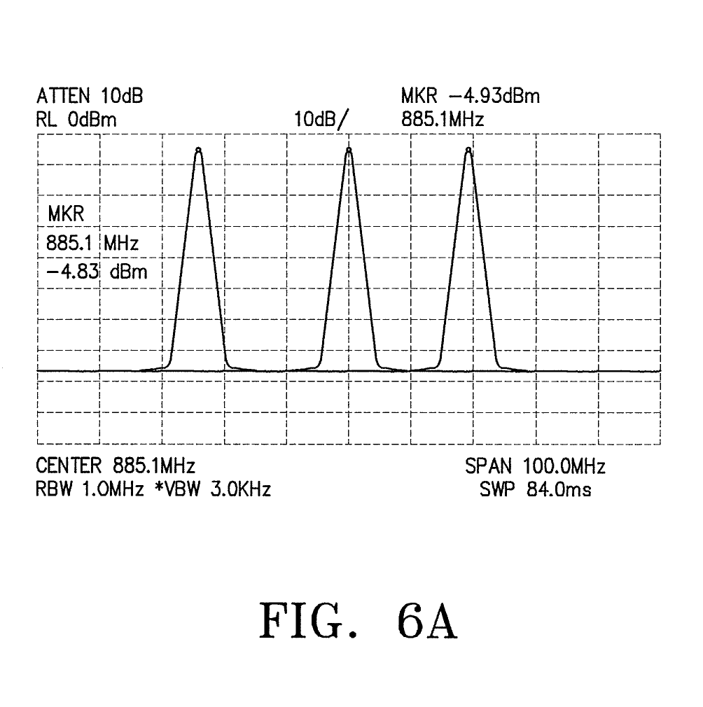

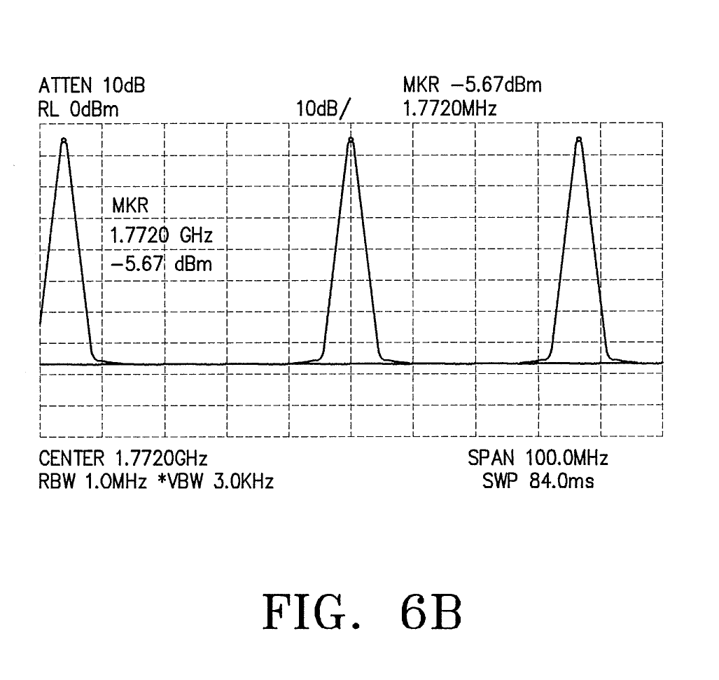

FIGS. 5A and 5B show measured variable scopes of the transmission frequency band of the VCO illustrated in FIG. 2 when the control voltage Vt varies from 0.8 V to 2.5 V and the frequency band switching control voltage V_{SW} is 0 V (“LOW” level). FIGS. 6A and 6B illustrate measured variable scopes of a reception frequency band of the VCO illustrated in FIG. 2 when the control voltage Vt varies from 0.8 V to 2.5 V and the frequency band switching control voltage V_{SW} is 2.5 V (“HIGH” level). FIG. 5A illustrates the transmission frequency band variable scope regarding a fundamental frequency, wherein a center frequency is 943.7 MHz, and FIG. 5B shows the transmission frequency band variable scope regarding the second harmonic component, wherein a center frequency is 1888 MHz (1.8880 GHz). FIG. 6A shows the reception frequency band variable scope regarding a fundamental frequency, wherein a center frequency is 885.1 MHz, and FIG. 6B shows the reception frequency band variable scope regarding the second harmonic component, wherein a center frequency is 1772 MHz (1.7720 GHz). In conclusion, as illustrated in FIGS. 5A, 5B, 6A and 6B, the measured variable scopes of the transmission/reception frequency bands satisfy transmission/reception frequency bands required in the DECT system.

As described above, since a voltage-controlled variable tuning circuit according to the present invention switches a frequency band by varying a capacitance instead of an inductance (i.e., the length of the inductor), the voltage-controlled variable tuning circuit can be easily embodied even though the frequency band is higher. In addition, when the harmonic component is applied to the PLL, once the PLL is locked to the fundamental frequency band, it is also locked to the second harmonic band, thereby increasing the number of frequency bands, which can be covered by a single VCO.

While the invention has been shown and described with reference to a certain preferred embodiment thereof, it will be understood by those skilled in the art that various changes in form and details may be made therein without departing from the spirit and scope of the invention as defined by the appended claims. In particular, while the invention has been described with reference to an embodiment where the voltage-controlled variable tuning circuit is applied to the DECT system, the voltage-controlled variable tuning circuit can also be applied to other systems that use a single VCO for various frequency bands. In addition, while the invention has been described with reference to a case where a single VCO is used in common for two different frequency bands, the number of frequency bands which can be covered by a single VCO can be increased by increasing the number of cascaded capacitor-diode pairs connected in parallel to the capacitor 20 and properly performing an switching operation on the cascaded capacitor-diode pairs according to the frequency band.

What is claimed is:

1. A voltage-controlled variable tuning circuit for switching an oscillation frequency band of a VCO (Voltage Controlled Oscillator), the circuit comprising:
a first capacitor interposed between an oscillation circuit and a control voltage supply terminal for receiving a control voltage for switching an oscillation frequency;
a variable capacitor interposed between the control voltage supply terminal and a reference voltage terminal;
an inductor connected in parallel to the variable capacitor; and
a frequency band switching circuit with a second capacitor, for selectively connecting the second capacitor in parallel to the first capacitor according to a frequency band.

2. The voltage-controlled variable tuning circuit as claimed in claim 1, wherein the frequency band switching circuit comprises:
said second capacitor;
a switching element serially connected to the second capacitor, the serially-connected second capacitor-switching element pair being connected in parallel to the first capacitor; and
a frequency band switching control voltage supply terminal connected to a connection point between the second capacitor and the switching element, for supplying a frequency band switching control voltage for controlling a switching operation of the switching element.

3. The voltage-controlled variable tuning circuit as claimed in claim 2, wherein the switching element is turned on to connect the second capacitor in parallel to the first capacitor if the frequency band switching control voltage is at a first level, and turned off to open-circuit the second capacitor if the frequency band switching control voltage is at a second level.

4. The voltage-controlled variable tuning circuit as claimed in claim 3, wherein the switching element is a diode.
